(19) United States
(12) Patent Application Publication
(10) Pub. No.: US 2026/0182045 A1
(43) Pub. Date: Jun. 25, 2026

(54) ELECTROSTATIC DISCHARGE PROTECTION CIRCUIT COMPRISING REVERSE BLOCKING DIODE AND SEMICONDUCTOR DEVICE COMPRISING THE SAME

(71) Applicant: Samsung Electronics Co., Ltd., Suwon-si (KR)

(72) Inventors: Jaehyok Ko, Suwon-si (KR); Nakhun Kim, Suwon-si (KR); Pangyum Kim, Suwon-si (KR); Changin Park, Suwon-si (KR); Jongyeol Lee, Suwon-si (KR)

(21) Appl. No.: 19/418,968

(22) Filed: Dec. 13, 2025

(30) Foreign Application Priority Data
Dec. 20, 2024 (KR) 10-2024-0192966

(51) Int. Cl. H10D 89/60; H02H 9/02; H10D 30/00; H10D 30/43; H10D 30/62

(52) U.S. Cl. CPC H10D 89/611; H02H 9/02; H10D 30/43; H10D 30/502; H10D 30/6211

(57) ABSTRACT

An electrostatic discharge protection circuit includes a first diode including an anode connected to an input/output pad and a cathode, and configured to form an electrostatic discharge path of a positive charge generated in the input/output pad, a second diode connected between the input/output pad and a second supply voltage terminal to which a ground voltage is applied, and configured to form an electrostatic discharge path of a negative charge generated in the input/output pad, a first resistor configured to limit a current flowing between the input/output pad and an input/output driver, and a reverse blocking diode connected between the first diode and a first supply voltage terminal to which a first supply voltage greater than the ground voltage is applied. The input/output driver is connected between the first supply voltage terminal and the second supply voltage terminal.

### CROSS-REFERENCE TO RELATED APPLICATION(S)

This application is based on and claims priority under 35 U.S.C. § 119 to Korean Patent Application No. 10-2024-0192966, filed on Dec. 20, 2024, in the Korean Intellectual Property Office, the disclosure of which is incorporated by reference herein in its entirety.

### BACKGROUND

The inventive concept relates to an electrostatic discharge protection circuit and a semiconductor device including the electrostatic discharge protection circuit, and more particularly, to an electrostatic discharge protection circuit including a reverse blocking diode, and a semiconductor device including the electrostatic discharge protection circuit.

Electrostatic discharge (ESD) may cause semiconductor devices to malfunction or even damage the semiconductor devices. For example, when a semiconductor element is exposed to ESD, the semiconductor element may be destroyed or damaged, such as by destruction of a gate insulating film of a transistor within the semiconductor element. Accordingly, a semiconductor device may include an ESD protection element, and the ESD protection element may protect an internal circuit from ESD generated outside the semiconductor device. Sizes of elements included in the semiconductor device may be reduced due to the advancement of semiconductor processes, and an operating voltage of the elements included in the semiconductor device may be reduced to reduce power consumption. Thus, the ESD protection element is needed to operate reliably in various environments.

### SUMMARY

The inventive concept relates to an electrostatic discharge protection circuit in which static electricity may be efficiently discharged while an input/output driver operates stably, and a semiconductor device including the electrostatic discharge protection circuit.

According to an aspect of the inventive concept, an electrostatic discharge protection circuit includes a first diode including an anode connected to an input/output pad and a cathode, and configured to form an electrostatic discharge path of a positive charge generated in the input/output pad, a second diode connected between the input/output pad and a second supply voltage terminal to which a ground voltage is applied, and configured to form an electrostatic discharge path of a negative charge generated in the input/output pad, a first resistor configured to limit a current flowing between the input/output pad and an input/output driver, and a reverse blocking diode connected between the first diode and a first supply voltage terminal to which a first supply voltage greater than the ground voltage is applied. The input/output driver is connected between the first supply voltage terminal and the second supply voltage terminal.

According to an aspect of the inventive concept, a semiconductor device includes a plurality of input/output cells connected between a first power rail for providing a first supply voltage and a second power rail for providing a second supply voltage less than the first supply voltage, and a power clamp cell configured to discharge static electricity generated in the plurality of input/output cells. Each of the plurality of input/output cells includes an input/output driver connected between the first power rail and the second power rail, a first diode connected to an input/output pad, and configured to form an ESD path of a positive charge generated in the input/output pad, a second diode connected between the input/output pad and the second power rail, and configured to form an ESD path of a negative charge generated in the input/output pad, and a first resistor configured to limit a current flowing between the input/output pad and the input/output driver. The semiconductor device further includes a reverse blocking diode connected between the first power rail and the first diode.

According to an aspect of the inventive concept, a semiconductor device includes a first diode including an anode connected to an input/output pad and a cathode, and configured to form an electrostatic path of a positive charge generated in the input/output pad, a second diode connected between the input/output pad and a second supply voltage terminal to which a second supply voltage is applied, and configured to form an electrostatic path of a negative charge generated in the input/output pad, a bias generating circuit configured to generate a first reference voltage and a second reference voltage by distributing a voltage between the second supply voltage and a first supply voltage greater than second supply voltage, an input/output driver connected between a first supply voltage terminal to which the first supply voltage is applied and a second supply voltage terminal to which the second supply voltage is applied, and a reverse blocking diode connected between the first supply voltage terminal and the first diode. The input/output driver includes a plurality of p-type transistors connected in series with each other between the first supply voltage terminal and the input/output pad, and a plurality of n-type transistors connected in series between the second supply voltage terminal and the input/output pad.

### BRIEF DESCRIPTION OF THE DRAWINGS

Example embodiments of the inventive concept will be more clearly understood from the following detailed description taken in conjunction with the accompanying drawings in which:

FIG. 1 is a block diagram illustrating a semiconductor device according to an embodiment;

FIG. 2 is a circuit diagram illustrating a semiconductor device according to an embodiment;

FIG. 3 is a circuit diagram of a power clamp circuit of FIG. 2, according to an embodiment;

FIG. 4 is a circuit diagram of a resistor of FIG. 2 according to an embodiment;

FIG. 5 is a circuit diagram of an input/output driver of FIG. 2 according to an embodiment;

FIG. 6 is a diagram for describing a voltage applied to a body of a p-type transistor of the input/output driver of FIG. 2 according to an embodiment;

FIG. 7 is a circuit diagram illustrating a semiconductor device according to an embodiment;

FIG. 8 is a plan view for describing an arrangement of cells included in a semiconductor device according to an embodiment;

FIG. 9 is a plan view for describing an arrangement of cells included in a semiconductor device according to an embodiment;

FIG. 10 is a plan view for describing a layout of input/output cells according to an embodiment;

FIGS. 11A to 11D are diagrams illustrating examples of a field-effect transistor of an input/output cell included in a semiconductor device according to example embodiments; and

FIG. 12 is a circuit diagram illustrating a semiconductor device according to an embodiment.

### DETAILED DESCRIPTION OF THE EMBODIMENTS

Below, various embodiments are described with reference to the accompanying drawings.

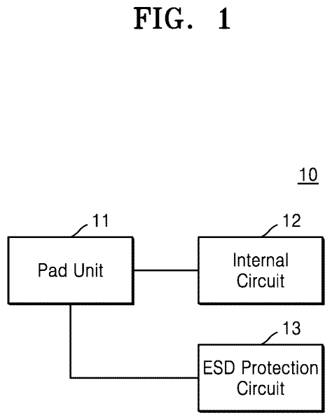

FIG. 1 is a block diagram illustrating a semiconductor device 10 according to an embodiment.

Referring to FIG. 1, the semiconductor device 10 may include a pad unit 11, an internal circuit 12, and an electrostatic discharge (ESD) protection circuit 13. The ESD protection circuit 13 refers to an electrostatic discharge protection circuit, and the electrostatic discharge is referred to as ESD.

The pad unit 11 may include an input/output pad to which a signal input from or output to the outside is applied, a power voltage pad to which a power voltage (a first supply voltage) is applied, and a ground voltage pad to which a ground voltage (a second supply voltage) is applied. The pad unit 11 may be electrically connected to the internal circuit 12 and the ESD protection circuit 13.

The semiconductor device 10 may perform various functions. The semiconductor device 10 may be a chip or die, or may be a semiconductor package including at least one chip or die. For example, the semiconductor device 10 may be a memory device, such as static random access memory (SRAM), dynamic RAM (DRAM), mobile DRAM, a flash memory device, electrically erasable programmable read-only memory (EEPROM), resistive RAM (PRAM), phase-change RAM (RRAM), ferroelectric RAM, or the like, but is not limited thereto. In some embodiments, for example, the semiconductor device 10 may be a system semiconductor device, such as a central processing unit (CPU), an application processor (AP), a graphics processing unit (GPU), a multimedia semiconductor device, a sensor, an artificial intelligence (AI) semiconductor device, or may be a system-on-chip (SoC).

The internal circuit 12 may be protected from ESD through the ESD protection circuit 13. The ESD protection circuit 13 may prevent damage to semiconductor elements of the internal circuit 12 caused by static electricity generated in the pad unit 11, or may provide an ESD path so that the internal circuit 12 may operate stably.

Due to the advancement of semiconductor processes, sizes of elements included in the internal circuit 12 may be reduced, and a junction depth and a thickness of gate oxide may be reduced. In addition, for low power consumption and high operating speed, an operating voltage of the internal circuit 12, i.e., a voltage difference between a first supply voltage and a second supply voltage (e.g., a ground voltage), may be reduced. Due to the above, the internal circuit 12 may include an input/output driver for performing a fail-safe operation, or may include an input/output driver including p-type transistors in a stack structure and n-type transistors in a stack structure, and the internal circuit 12 may be efficiently protected through an ESD path of the ESD protection circuit 13 according to the inventive concept.

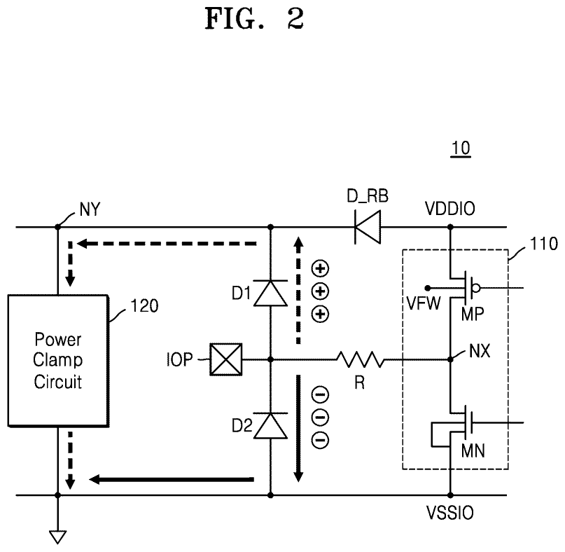

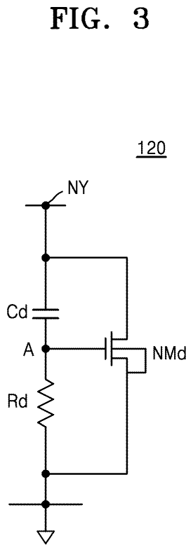

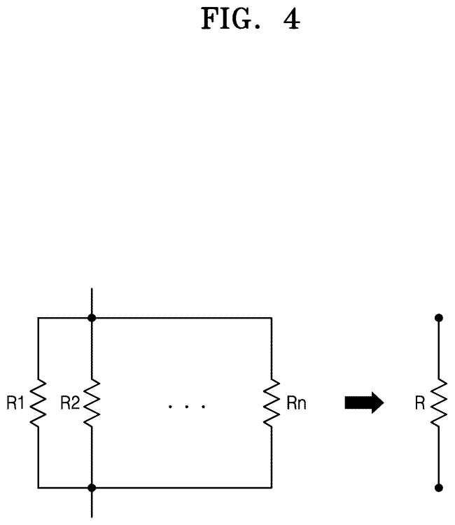

FIG. 2 shows a circuit diagram illustrating the semiconductor device 10 according to an embodiment, in which a detailed configuration of the semiconductor device 10 of FIG. 1 is shown. FIG. 3 is a circuit diagram of a power clamp circuit 120 of FIG. 2, according to an embodiment. FIG. 4 is a circuit diagram of a resistor R of FIG. 2 according to an embodiment.

Referring to FIG. 2, the semiconductor device 10 may include an input/output driver 110 included in the internal circuit 12 of FIG. 1, and an ESD protection circuit (e.g., 13 of FIG. 1). The ESD protection circuit may include the power clamp circuit 120, a reverse blocking diode D_RB, a first diode D1, a second diode D2, and the resistor R.

The input/output driver 110 may pull up or pull down a voltage level of an input/output pad in response to a driving signal, thereby providing an output signal to an input/output pad IOP. The input/output driver 110 may include a pull-up driver and a pull-down driver which are connected in series between a first supply voltage VDDIO terminal and a second supply voltage VSSIO (e.g., a ground voltage) terminal. In other words, the first supply voltage VDDIO and the second supply voltage VSSIO may be supply voltages for operating the input/output driver 110. The pull-up driver and the pull-down driver may be connected to a connection node NX, and the input/output pad IOP may also be connected to the connection node NX.

The pull-up driver may include a p-type transistor MP with a gate terminal to which a driving signal is applied, and the pull-down driver may include an n-type transistor MN with a gate terminal to which a driving signal is applied. However, the inventive concept is not limited thereto, and a structure of the input/output driver 110 may variously modified depending on the scheme by which the input/output driver 110 transmits data via the input/output pad IOP.

The input/output driver 110 may be a fail-safe input/output driver for performing a fail-safe function. In an embodiment, the input/output driver 110 may operate even when a voltage level of the first supply voltage VDDIO and the second supply voltage VSSIO for driving the input/output driver 110 is different from the maximum voltage level allowed by the input/output pad IOP. For example, even when the voltage level of the first supply voltage VDDIO is 1.8 V, the input/output driver 110 may be configured such that the input/output pad IOP may tolerate 3.3 V.

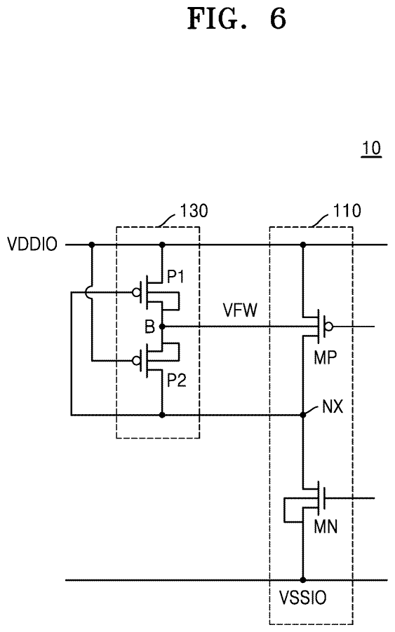

A body of the n-type transistor MN included in the pull-down driver of the input/output driver 110 may be connected to a source, and a body of the p-type transistor MP included in the pull-up driver may have a voltage which varies according to a well bias control signal VFW. For example, when the voltage of the input/output pad IOP is higher than the first supply voltage VDDIO, the body of the p-type transistor MP may be electrically connected to the connection node NX (or may be received a voltage of the first node NX) as shown in FIG. 6, and when the voltage of the input/output pad IOP is less than the first supply voltage VDDIO, the body of the p-type transistor MP may receive the first supply voltage VDDIO (or may be electrically connected to the first supply voltage VDDIO terminal) as shown in FIG. 6.

The ESD protection circuit may include the first diode D1 and the second diode D2 which are connected in series between a node NY and the second supply voltage VSSIO terminal. The first diode D1 may receive static electricity of a positive charge greater than or equal to the voltage of the Node NY through the input/output pad IOP and discharge the received static electricity to the node NY or to the second supply voltage VSSIO terminal via the power clamp circuit 120. The second diode D2 may receive static electricity of a negative charge less than or equal to the second supply voltage VSSIO (the ground voltage) via the input/output pad IOP and discharge the received static electricity to the second supply voltage VSSIO terminal.

Thus, in the ESD protection circuit according to the inventive concept, static electricity may be efficiently discharged with low on-resistance (Ron) by forward turn-on of the first diode D1 for static electricity of a positive charge and forward turn-on of the second diode D2 for static electricity of a negative charge.

Referring to FIGS. 2 and 3, the power clamp circuit 120 may be connected between the node NY and the second supply voltage VSSIO terminal. The power clamp circuit 120 may detect an abnormal change of a voltage of the node NY caused by an ESD event and form or block an ESD path. In an embodiment, the power clamp circuit 120 may be implemented to include a capacitor Cd, a resistor Rd, and a transistor NMd. The transistor NMd may be connected between the node NY and the second supply voltage VSSIO terminal, the capacitor Cd may be connected between the node NY and a gate of the transistor NMd, and the resistor Rd may be connected between the second supply voltage VSSIO terminal and the gate of the transistor NMd. The transistor NMd may be an n-type transistor. A turn-on voltage of the transistor NMd between the node NY and the second supply voltage VSSIO terminal may be determined by the resistor Rd and the capacitor Cd which are connected in series with each other.

When static electricity of a positive charge is generated in the input/output pad IOP, the capacitor Cd may flow a resulting ESD current to a node A, and the resistor Rd may receive the current discharged from the capacitor Cd via the node A and generate a voltage. The transistor NMd may receive the generated voltage at the gate thereof via the resistor Rd, and when the voltage received at the gate is greater than a threshold voltage of the transistor NMd, a current may flow through a drain-source path, thereby allowing the ESD current to flow through the drain-source path. Thus, the power clamp circuit 120 may receive static electricity of a positive charge via the node NY and discharge the received static electricity to the second supply voltage VSSIO terminal.

However, the power clamp circuit 120 shown in FIG. 3 is only an example of the power clamp circuit 120, and the power clamp circuit 120 may be implemented in various circuit structures.

Referring to FIG. 2 again, the ESD protection circuit may include the reverse blocking diode D_RB which is connected between the first supply voltage VDDIO terminal and the first diode D1. A cathode of the reverse blocking diode D_RB may be connected to a cathode of the first diode D1, i.e., the node NY, and an anode of the reverse blocking diode D_RB may be connected to the first supply voltage VDDIO terminal.

The reverse blocking diode D_RB may help the input/output driver 110 maintain the fail-safe function. For example, in a situation where the voltage of the input/output pad IOP is greater than a value obtained by adding a built-in voltage of the first diode D1 to the first supply voltage VDDIO, the reverse blocking diode D_RB may electrically block the connection between the node NY and the first supply voltage VDDIO terminal so that the input/output pad IOP may operate stably. The input/output driver 110 of the fail-safe function may operate stably within a range where a reverse breakdown phenomenon of the reverse blocking diode D_RB does not occur.

In an embodiment, a size of the reverse blocking diode D_RB may be less than a size of the first diode D1 or a size of the second diode D2. For example, a size of an area occupied by the reverse blocking diode D_RB on a substrate may be less than a size of an area occupied by the first diode D1 or the second diode D2 on the substrate.

In an embodiment, the reverse blocking diode D_RB may also be connected to a first diode which is connected to an input/output pad of an input/output driver other than the input/output driver 110 shown in FIG. 2. For example, the cathode of the reverse blocking diode D_RB may be connected to a cathode of a diode having an anode connected to a first input/output pad of a first input/output driver included in the semiconductor device 10, and may also be connected to a cathode of a diode having an anode connected to a second input/output pad of a second input/output driver included in the semiconductor device 10.

Referring to FIGS. 2 and 4, the ESD protection circuit may include the resistor R, which is connected between the input/output pad IOP and the input/output driver 110. The resistor R may be connected between the input/output pad IOP and the connection node NX of the input/output driver 110 and may limit a current flowing between the input/output pad IOP and the connection node NX. Thus, the p-type transistor MP and the n-type transistor MN of the input/output driver 110, which may be damaged during ESD, may be protected. The resistor R may be, for example, 25Ω or 50Ω. In an embodiment, the resistor R may be implemented to have a relatively small resistance value by connecting, in parallel, a plurality of resistors R1 to Rn having relatively large resistance values.

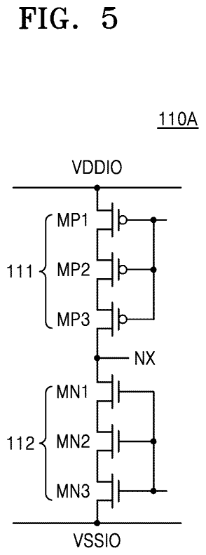

FIG. 5 is a circuit diagram of an input/output driver 110 of FIG. 2 according to an embodiment.

Referring to FIG. 5, the input/output driver 110A may include a pull-up driver 111 and a pull-down driver 112. The pull-up driver 111 may include a plurality of p-type transistors MP1 to MP3 having a stack structure, which are connected in series with each other. A driving signal may be input to a gate of each of the plurality of p-type transistors MP1 to MP3. The pull-down driver 112 may include a plurality of n-type transistors MN1 to MN3 having a stack structure, which are connected in series with each other. A driving signal may be input to a gate of each of the plurality of n-type transistors MN1 to MN3. A circuit configuration of the input/output driver 110A shown in FIG. 5 is only an example, and the number of p-type transistors included in the pull-up driver 111 and the number of n-type transistors included in the pull-down driver 112 may be variously modified.

FIG. 6 is a diagram for describing a voltage applied to a body of the p-type transistor MP of the input/output driver 110 of FIG. 2 according to an embodiment.

Referring to FIGS. 2 and 6, the body of the p-type transistor MP included in the pull-up driver of the input/output driver 110 may have a voltage which varies depending on the well bias control signal VFW. For example, when the voltage of the input/output pad IOP is higher than the first supply voltage VDDIO, the body of the p-type transistor MP may be electrically connected to the connection node NX (or may be received a voltage of the first node NX), and when the voltage of the input/output pad IOP is less than the first supply voltage VDDIO, the body of the p-type transistor MP may receive the first supply voltage VDDIO (or may be electrically connected to the first supply voltage VDDIO terminal).

The semiconductor device 10 may further include a body voltage generation circuit 130 for generating a body voltage of the body of the p-type transistor MP. In an embodiment, the body voltage generation circuit 130 may include a first p-type transistor P1 and a second p-type transistor P2, which are connected in series with each other between the first supply voltage VDDIO terminal and the connection node NX. A gate of the first p-type transistor P1 may be connected to the connection node NX and a gate of the second p-type transistor P2 may be connected to the first supply voltage VDDIO terminal. The well bias control signal VFW may be output from a node B to which the first p-type transistor P1 and the second p-type transistor P2 are connected. In an embodiment, the body of the first p-type transistor P1 and the body of the second p-type transistor P2 may be connected to the node B.

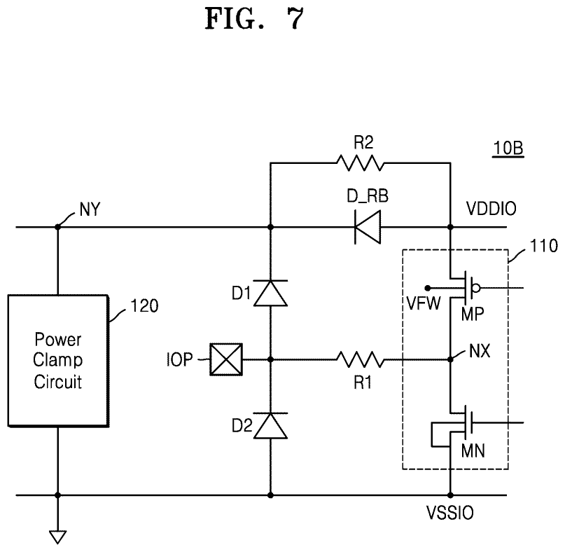

FIG. 7 shows a circuit diagram illustrating a semiconductor device 10B according to an embodiment, in which a detailed configuration of the semiconductor device 10 of FIG. 1 is shown. In FIG. 7, redundant descriptions of symbols identical to those of FIG. 2 may be omitted.

Referring to FIG. 7, the semiconductor device 10B may include the input/output driver 110 included in the internal circuit 12 of FIG. 1, and an ESD protection circuit (e.g., 13 of FIG. 1). The ESD protection circuit may include the power clamp circuit 120, the reverse blocking diode D_RB, the first diode D1, the second diode D2, a first resistor R1, and a second resistor R2. The first resistor R1 may be identical to the resistor R described with reference to FIG. 2.

The second resistor R2 included in the ESD protection circuit may be connected in parallel with the reverse blocking diode D_RB. The second resistor R2 may be connected between the first supply voltage VDDIO terminal and the node NY. In an embodiment, the second resistor R2 may be greater than the first resistor R1 and may have, for example, a size of several kiloohms to tens of kiloohms.

During a normal operation of the input/output driver 110, a temporary current may be generated in the power clamp circuit 120. The semiconductor device 10B may include the second resistor R2 so that a temporary current, which may be generated in the power clamp circuit 120, may be prevented.

In an embodiment, the second resistor R2 may also be connected to a first diode which is connected to an input/output pad of an input/output driver other than the input/output driver 110 shown in FIG. 7. For example, one terminal of the second resistor R2 may be connected to a cathode of a first diode having an anode connected to a first input/output pad of a first input/output driver included in the semiconductor device 10B, and may also be connected to a cathode of a second diode having an anode connected to a second input/output pad of a second input/output driver included in the semiconductor device 10B. The first supply voltage VDDIO may be applied to the other terminal of the second resistor R2.

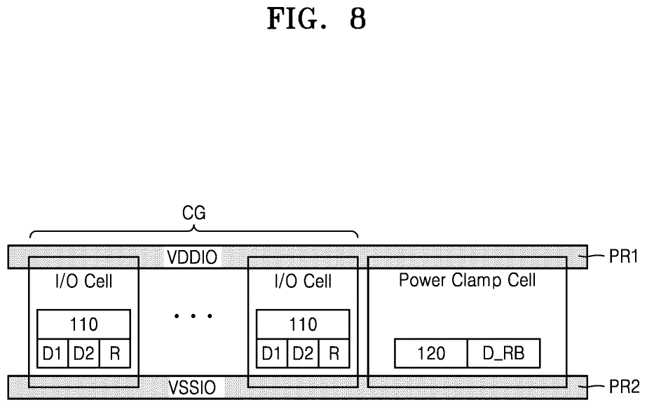

FIG. 8 is a plan view for describing an arrangement of cells included in a semiconductor device according to an embodiment.

Referring to FIG. 8, the semiconductor device may include an input/output cell group CG including a plurality of input/output cells, and a power clamp cell connected to the input/output cell group CG. Each of the plurality of input/output cells may include an input/output driver (110 of FIG. 2 or 110A of FIG. 5), the first diode D1, the second diode D2, and a resistor (R of FIG. 2 or R1 of FIG. 7).

The power clamp cell may include a power clamp circuit (120 of FIG. 2) and the reverse blocking diode D_RB. The power clamp cell may further include a second resistor (R2 of FIG. 7). In an embodiment, a size (area) of each of the first diode D1 and the second diode D2 included in each of the plurality of input/output cells may be greater than a size (area) of the reverse blocking diode D_RB included in the power clamp cell.

The semiconductor device according to the inventive concept may include a plurality of input/output cells and a plurality of power clamp cells so that one power clamp cell is connected to one input/output cell group CG, rather than including a plurality of power clamp cells corresponding to the plurality of input/output cells on a one-to-one basis. For example, the plurality of input/output cells included in one input/output cell group CG may have a structure of sharing the power clamp cells. In some embodiments, the semiconductor device may include one power clamp cell connected to all of the plurality of input/output cells that are included.

For example, one reverse blocking diode D_RB, one second resistor R2, and one power clamp circuit 120 may be connected to a plurality of input/output drivers 110, and may be connected to a plurality of first diodes D1 and a plurality of second diodes D2.

The semiconductor device may include a first power rail PR1 and a second power rail PR2 for supplying voltage to a semiconductor element. The first power rail PR1 may provide the first supply voltage VDDIO to a semiconductor element included in the semiconductor device, and the second power rail PR2 may provide the second supply voltage VSSIO (e.g., a ground voltage) to the semiconductor element. In the semiconductor element described with reference to FIG. 2, etc., being connected to the first supply voltage VDDIO terminal may indicate being connected to the first power rail PR1, and being connected to the second supply voltage VSSIO terminal may indicate being connected to the second power rail PR2.

Each of the plurality of input/output cells may be connected between the first power rail PR1 and the second power rail PR2 and may receive the first supply voltage VDDIO and the second supply voltage VSSIO. In addition, the power clamp cell may be connected between the first power rail PR1 and the second power rail PR2 and may receive the first supply voltage VDDIO and the second supply voltage VSSIO.

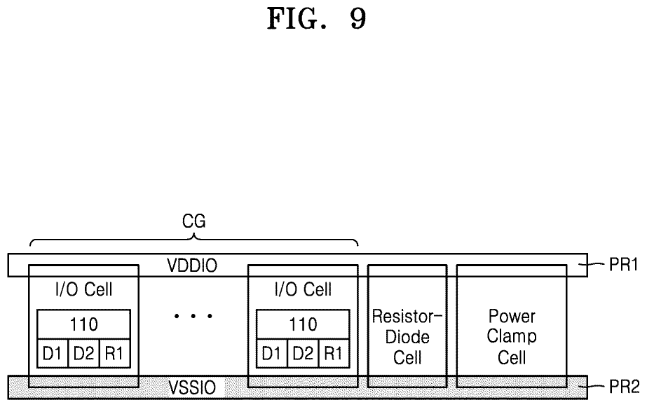

FIG. 9 is a plan view for describing an arrangement of cells included in a semiconductor device according to an embodiment.

Referring to FIG. 9, the semiconductor device may include an input/output cell group CG including a plurality of input/output cells, a power clamp cell and a resistor-diode cell connected to the input/output cell group CG. Each of the plurality of input/output cells may include an input/output driver (110 of FIG. 2 or 110A of FIG. 5), the first diode D1, the second diode D2, and the first resistor R1 (or R of FIG. 2). The power clamp cell may include a power clamp circuit (120 of FIG. 2).

The resistor-diode cell may include a reverse blocking diode (D_RB of FIG. 2) and a second resistor (R2 of FIG. 7). However, the present invention is not limited thereto, and the resistor-diode cell may include only the reverse blocking diode (D_RB of FIG. 2). The resistor-diode cell may be arranged adjacent to the power clamp cell. In an embodiment, a size (area) of the reverse blocking diode D_RB included in the resistor-diode cell may be less than a size (area) of each of the first diode D1 and the second diode D2 included in each of the plurality of input/output cells.

The semiconductor device according to the inventive concept may include a plurality of input/output cells and a plurality of power clamp cells so that one power clamp cell and one resistor-diode cell are connected to one input/output cell group CG including a set of input/output cells among the plurality input/output cells. In some embodiments, the semiconductor device may include one power clamp cell and one resistor-diode cell that are connected to all of the plurality of input/output cells. Accordingly, one reverse blocking diode D_RB, one second resistor R2, and one power clamp circuit 120 may be connected to the plurality of input/output drivers 110, and may be connected to the plurality of first diodes D1 and the plurality of second diodes D2.

The semiconductor device may include the first power rail PR1 and the second power rail PR2 for supplying voltage to a semiconductor element. The first power rail PR1 may provide the first supply voltage VDDIO to a semiconductor element, and the second power rail PR2 may provide the second supply voltage VSSIO (e.g., a ground voltage) to the semiconductor element. Each of the plurality of input/output cells may be connected to the first power rail PR1 and the second power rail PR2 and may receive the first supply voltage VDDIO and the second supply voltage VSSIO. In addition, the power clamp cell may be connected to the second power rail PR2 and the resistor-diode cell may be connected to the first power rail PR1.

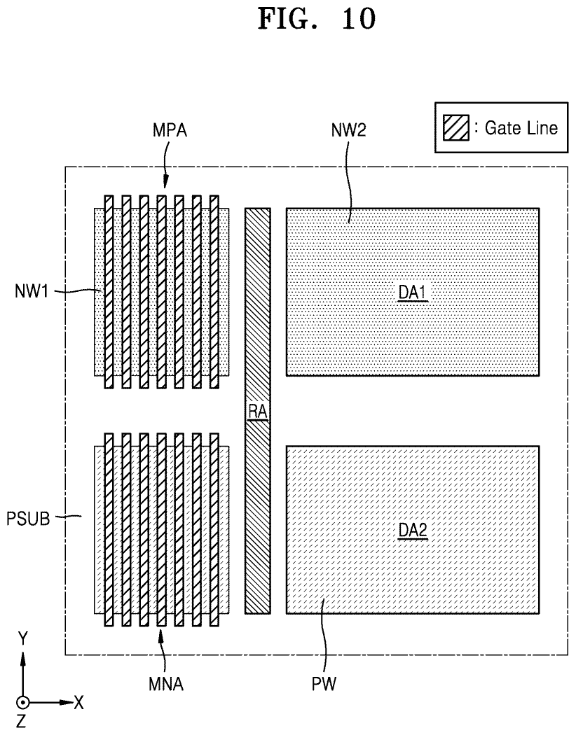

FIG. 10 is a plan view for describing a layout of input/output cells according to an embodiment. An X-axis direction and a Y-axis direction as used herein may be referred to as a first horizontal direction and a second horizontal direction, respectively, and a Z-axis direction may be referred to as a vertical direction.

Referring to FIGS. 2 and 10, an input/output cell may include the p-type transistor MP included in an input/output driver and an n-type transistor MN included in the input/output driver, may include the resistor R of FIG. 2 or the first resistor R1 of FIG. 7, and may include the first diode D1 and the second diode D2.

The input/output cell may include a p-channel field-effect transistor (PFET) area MPA in which the p-type transistor MP is formed and an n-channel field-effect transistor (NFET) area MNA in which the n-type transistor MN is formed, may include a resistance area RA in which the resistor R of FIG. 2 or the first resistor R1 of FIG. 7 is formed, and may include a first diode area DA1 in which the first diode D1 is formed and a second diode area DA2 in which the second diode D2 is formed.

A substrate PSUB may include a silicon (Si) or a germanium (Ge), and a group III-V compound, such as GaAs, AlGaAs, InAs, InGaAs, InSb, GaSb, InGaSb, InP, GaP, InGaP, InN, GaN, or InGaN. In an embodiment, the substrate PSUB may be a silicon on insulator (SOI) substrate or a germanium on insulator (GOI) substrate. In an embodiment, the substrate PSUB may be doped with p-type impurities.

In an embodiment, the PFET area MPA and the NFET area MNA of the input/output cell may be arranged parallel to each other in the Y-axis direction. The PFET area MPA and the NFET area MNA of the input/output cell may include active areas extending in the X-axis direction on the substrate PSUB. The active area of the PFET area MPA may be formed in a first N-well NW1 formed within the substrate PSUB. On the other hand, the active area of the NFET area MNA may be formed in the substrate PSUB doped with p-type impurities, or in a P-well formed within the substrate PSUB.

The PFET area MPA and the NFET area MNA of the input/output cell may include gate lines extending in the Y-axis direction on the substrate PSUB. The active areas and the gate lines in the PFET area MPA and the NFET area MNA may form a field-effect transistor (FET). The gate line may include a work function metal containing layer and a gapfill metal film. For example, the work function metal containing layer may include at least one metal among titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd), and the gapfill metal film may include a W film or an aluminum (Al) film. In an embodiment, the gate line may include a stack structure of TiAlC/TiN/W, a stack structure of TiN/TaN/TiAlC/TiN/W, or a stack structure of TiN/TaN/TiN/TiAlC/TiN/W.

In the semiconductor device according to the inventive concept, an effective discharge path for ESD occurring in the input/output pad IOP may be provided through the first diode D1 and the second diode D2, and the p-type transistor MP and the n-type transistor MN of the input/output driver 110 may be protected from ESD through the resistor R (or the first resistor R1 of FIG. 7) and the reverse blocking diode D_RB. Thus, when forming the p-type transistor MP and the n-type transistor MN in the input/output cell, existing ESD design rules may not apply, and design rules for forming general transistors may apply. Accordingly, an interval (poly pitch) between gate lines formed in the PFET area MPA and the NFET area MNA may be reduced, and an area of the PFET area MPA and the NFET area MNA may be reduced. In this reduced area, the resistance area RA, the first diode area DA1, and the second diode area DA2 may be arranged so that an overall area of the input/output cell may be prevented from increasing.

The first diode area DA1 may be arranged in parallel with the PFET area MPA in the X-axis direction. The first diode area DA1 may be formed in a second N-well NW2 formed within the substrate PSUB. The first diode D1 formed in the first diode area DA1 may be formed by a PN junction of the second N-well NW2 and a p-type region formed on the second N-well NW2.

The first N-well NW1 and the second N-well NW2 may be electrically disconnected by an element isolation layer (e.g., shallow trench isolation (STI)). A well bias control signal may be applied to a body of the p-type transistor MP formed in the first N-well NW1, a cathode of the first diode D1 formed in the second N-well NW2 may be connected to the node NY, and the first N-well NW1 and the second N-well NW2 may be electrically isolated from each other.

The second diode area DA2 may be arranged in parallel with the NFET area MNA in the X-axis direction. The second diode area DA2 may be formed in a P-well PW formed in the substrate PSUB or in the substrate PSUB. The second diode D2 formed in the second diode area DA2 may be formed by a PN junction of the P-well PW and an N-type region formed on the P-well PW.

In FIG. 10, the NFET area MNA and the second diode area DA2 are shown as being isolated from each other. However, the second supply voltage VSSIO (ground voltage) is applied to the body of the n-type transistor MN formed in the NFET area MNA and the second supply voltage VSSIO is also applied to an anode of the second diode D2 formed in the second diode area DA2, and thus, the NFET area MNA and the second diode area DA2 may not be electrically isolated from each other but may be connected to each other.

The resistance area RA may be arranged between the PFET area MPA and the first diode area DA1. In FIG. 10, the resistance area RA is shown as being also arranged between the NFET area MNA and the second diode area DA2. However, the present invention is not limited thereto, and the resistance area RA may be arranged only on an element isolation layer formed between the PFET area MPA and the first diode area DA1 or only on an element isolation layer formed between the NFET area MNA and the second diode area DA2. In the resistance area RA, a resistor (R or R1) may be implemented such that a plurality of resistors are connected in parallel with each other.

Internal wiring for mutually connecting the semiconductor elements (e.g., the p-type transistor MP, the n-type transistor MN, the resistor (R or R1), the first diode D1, and the second diode D2) formed in the input/output cell may be formed in the input/output cell, and a plurality of wiring layers in which the internal wiring is formed may be formed to be stacked in the input/output cell. In addition, the semiconductor device may include a plurality of wiring layers in which routing wiring for mutually connecting the input/output cell and the power clamp cell (or the resistor-diode cell) are formed. Patterns respectively formed in the plurality of wiring layers may include a metal, conductive metal nitride, metal silicide, or a combination thereof.

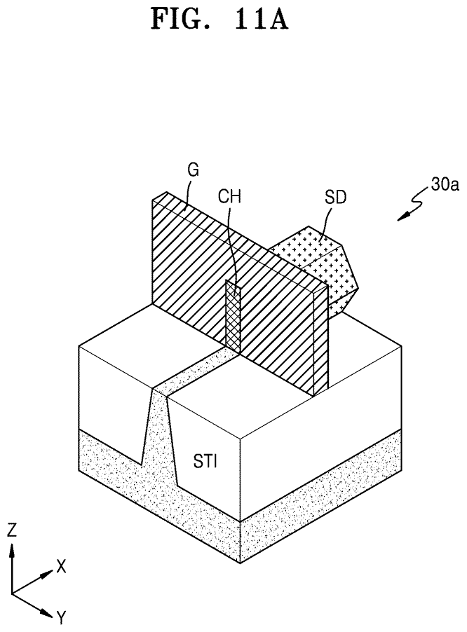

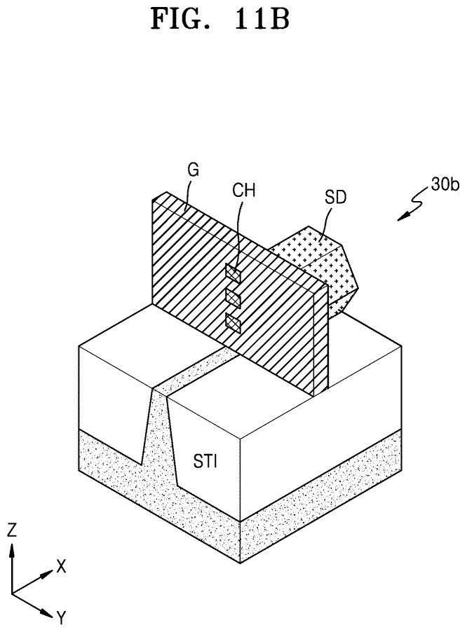

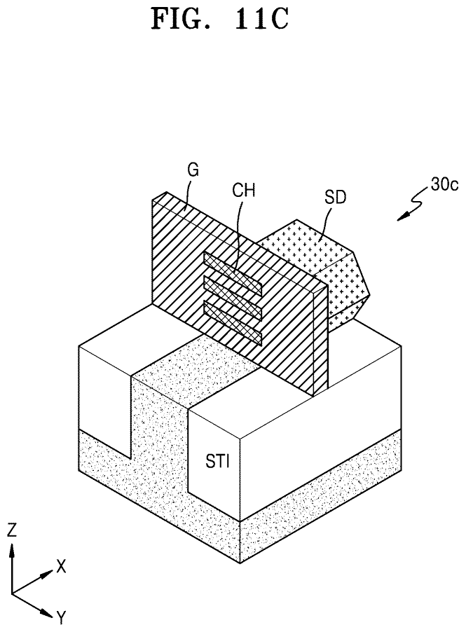

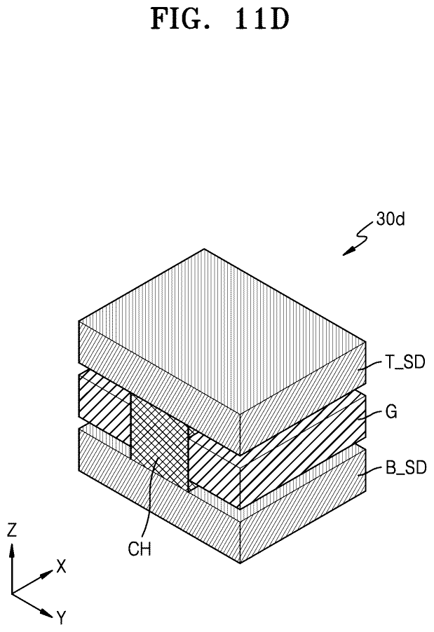

FIGS. 11A to 11D are diagrams illustrating examples of an FET of an input/output cell included in a semiconductor device according to example embodiments. For example, FIG. 11A shows a fin field-effect transistor (FinFET) 30a, FIG. 11B shows a gate-all-around field effect transistor (GAAFET) 30b, FIG. 11C shows a multi-bridge channel field-effect transistor (MBCFET) 30c, and FIG. 11D shows a vertical field-effect transistor (VFET) 30d. For convenience of illustration, FIGS. 11A to 11C show a state in which one of three source and drain regions is removed, and FIG. 11D shows a cross-section of the VFET 30d taken along a plane parallel to a plane including the Y-axis and the Z-axis and passing through a channel CH of the VFET 30d.

Referring to FIG. 11A, the FinFET 30a may be formed by a fin-shaped active pattern extending in the X-axis direction between adjacent isolation layers STI, and a gate electrode G extending in the Y-axis direction. Source and drain regions SD may be formed at opposite sides of the gate electrode G, respectively, so that the source and the drain may be spaced apart from each other in the X-axis direction. An insulating film may be formed between the channel CH and the gate electrode G. In some embodiments, the FinFET 30a may be formed by a plurality of active patterns and the gate electrode G spaced apart in the Y-axis direction.

Referring to FIG. 11B, the GAAFET 30b may be formed by active patterns (e.g., nanowires) spaced apart in the Z-axis direction and extending in the X-axis direction, and the gate electrode G extending in the Y-axis direction. Source and drain regions SD may be formed at opposite sides of the gate electrode G, respectively, so that the source and the drain may be spaced apart from each other in the X-axis direction. An insulating film may be formed between the channel CH and the gate electrode G. The number of nanowires included in the GAAFET 30b is not limited to that shown in FIG. 11B.

Referring to FIG. 11C, the MBCFET 30c may be formed by active patterns (e.g., nanosheets) spaced apart in the Z-axis direction and extending in the X-axis direction, and the gate electrode G extending in the Y-axis direction. The source and drain regions SD may be formed at opposite sides of the gate electrode G, respectively, so that the source and the drain may be spaced apart from each other in the Y-axis direction. An insulating film may be formed between the channel CH and the gate electrode G. The number of nanosheets included in the MBCFET 30c is not limited to that shown in FIG. 11C.

Referring to FIG. 11D, the VFET 30d may include a top source/drain T_SD and a bottom source/drain B_SD, which are spaced apart from each other in the Z-axis direction with the channel CH between the top source/drain T_SD and the bottom source/drain B_SD. The VFET 30d may include, between the top source/drain T_SD and the bottom source/drain B_SD, the gate electrode G surrounding the perimeter of the channel CH. An insulating film may be formed between the channel CH and the gate electrode G.

However, the p-type transistor (MP of FIG. 2) and the n-type transistor (MN of FIG. 2) included in the input/output cell, according to the inventive concept, are not limited to the FinFET 30a, the GAAFET 30b, the MBCFET 30c, or the VFET 30d. For example, the semiconductor device may include a Forksheet field-effect transistor (ForkFET) having a structure in which the nanosheets for the p-type transistors and the nanosheets for the n-type transistor are isolated by a dielectric wall so that the n-type transistor and the p-type transistor are closer to each other. In addition, the semiconductor device may include an FET, such as a complementary FET (CFET), a negative CFET (NCFET), or a carbon nanotube FET (CNT).

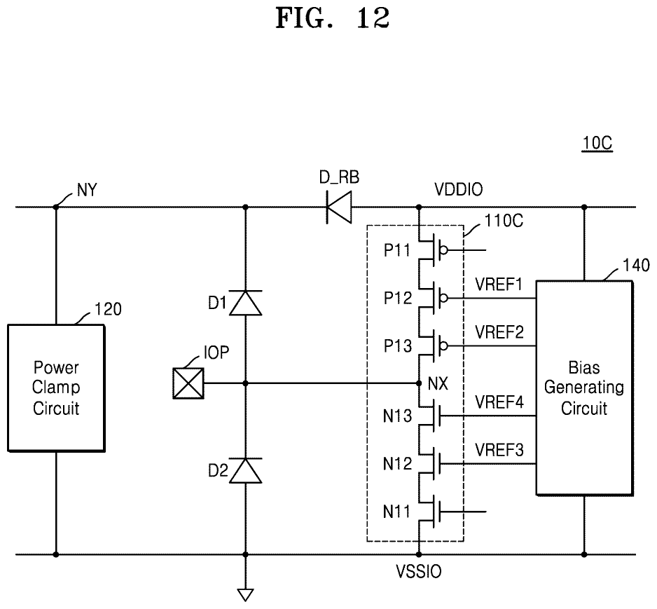

FIG. 12 shows a circuit diagram illustrating a semiconductor device 10C according to an embodiment, in which a detailed configuration of the semiconductor device 10 of FIG. 1 is shown.

Referring to FIG. 12, the semiconductor device 10C may include an input/output driver 110C and a bias generating circuit 14, which are included in the internal circuit 12 of FIG. 1, and an ESD protection circuit (e.g., 13 of FIG. 1). The ESD protection circuit may include the power clamp circuit 120, the reverse blocking diode D_RB, the first diode D1, and the second diode D2.

The input/output driver 110C may pull up or pull down a voltage level of an input/output pad IOP in response to a driving signal, thereby providing an output signal to the input/output pad IOP. The input/output driver 110C may include a pull-up driver and a pull-down driver which are connected in series between the first supply voltage VDDIO terminal and the second supply voltage VSSIO (e.g., a ground voltage) terminal. The pull-up driver and the pull-down driver may be connected to the connection node NX, and the input/output pad IOP may also be connected to the connection node NX. The pull-up driver may include a plurality of p-type transistors P11 to P13 connected in series and the pull-down driver may include a plurality of n-type transistors N11 to N13 connected in series. In FIG. 12, the pull-up driver includes three p-type transistors and the pull-down driver includes three n-type transistors. However, the present invention is not limited thereto, and the number of p-type transistors included in the pull-up driver and the number of n-type transistors included in the pull-down driver may be variously modified.

The input/output driver 110C may be an input/output driver which does not perform a fail-safe function. Bodies of the plurality of n-type transistors N11 to N13 may be connected to respective sources, and bodies of the plurality of p-type transistors P11 to P13 may be connected to respective sources.

From among the plurality of p-type transistors P11 to P13 included in the pull-up driver, a driving signal may be input to a gate of the first p-type transistor P11 and a reference voltage may be applied to gates of the remaining p-type transistors P12 and P13. For example, a first reference voltage VREF1 may be applied to the gate of the second p-type transistor P12 and a second reference voltage VREF2 may be applied to the gate of the third p-type transistor P13.

From among the plurality of n-type transistors N11 to N13 included in the pull-down driver, a driving signal may be input to a gate of the first n-type transistor N11 and a reference voltage may be applied to gates of the remaining n-type transistors N12 and N13. For example, a third reference voltage VREF3 may be applied to the gate of the second n-type transistor N12 and a fourth reference voltage VREF4 may be applied to the gate of the third n-type transistor N13.

Sizes of elements included in the semiconductor device 10C may be reduced due to the advancement of semiconductor processes, and a voltage range within which the elements included in the semiconductor device 10C may stably operate may be reduced. The input/output driver 110C of the semiconductor device 10C according to the inventive concept includes the plurality of p-type transistors P11 to P13 and the plurality of n-type transistors N11 to N13, which are stacked in series, so that each of the plurality of p-type transistors P11 to P13 and the plurality of n-type transistors N11 to N13 may operate in a narrow voltage range, thereby enabling the input/output driver 110C to operate stably.

A bias generating circuit 140 may generate a plurality of reference voltages, e.g., the first to fourth reference voltages VREF1 to VREF4. The bias generating circuit 140 may be connected to the first supply voltage VDDIO terminal and the second supply voltage VSSIO terminal and may generate the plurality of reference voltages between the first supply voltage VDDIO and the second supply voltage VSSIO. In an embodiment, the bias generating circuit 140 may be a voltage distributor including a plurality of resistors.

The ESD protection circuit may include the first diode D1 and the second diode D2 which are connected in series between the node NY and the second supply voltage VSSIO terminal. The first diode D1 may receive static electricity of a positive charge greater than or equal to the voltage of the Node NY through the input/output pad IOP and discharge the received static electricity to the node NY or to the second supply voltage VSSIO terminal via the power clamp circuit 120. The second diode D2 may receive static electricity of a negative charge less than or equal to the second supply voltage VSSIO (the ground voltage) via the input/output pad IOP and discharge the received static electricity to the second supply voltage VSSIO terminal. Therefore, in the ESD protection circuit according to the inventive concept, static electricity may be efficiently discharged with a low on resistance Ron by forward turning on the first diode D1 for static electricity of a positive charge and forward turning on the second diode D2 for static electricity of a negative charge.

The ESD protection circuit may include the reverse blocking diode D_RB which is connected between the first supply voltage VDDIO terminal and the first diode D1. The cathode of the reverse blocking diode D_RB may be connected to the cathode of the first diode D1, i.e., the node NY, and the anode of the reverse blocking diode D_RB may be connected to the first supply voltage VDDIO terminal. In an embodiment, the semiconductor device 10C may further include a resistor (e.g., the second resistor R2 of FIG. 7) connected in parallel with the reverse blocking diode D_RB.

The reverse blocking diode D_RB may separate the first supply voltage VDDIO terminal and the node NY from each other. Therefore, even when the voltage of the node NY fluctuates significantly, the first supply voltage VDDIO may be prevented from fluctuating in relation to the voltage of the node NY, and the first supply voltage VDDIO may be stable. Accordingly, the plurality of reference voltages VREF1 to VREF4 generated in the bias generating circuit 140 may also be generated stably.

In an embodiment, the size of the reverse blocking diode D_RB may be less than the size of the first diode D1 or the size of the second diode D2. In other words, the size of the area occupied by the reverse blocking diode D_RB on the substrate may be less than the size of the area occupied by the first diode D1 or the second diode D2 on the substrate. In addition, in an embodiment, the reverse blocking diode D_RB may also be connected to a first diode which is connected to an input/output pad of an input/output driver other than the input/output driver 110C shown in FIG. 12.

While the inventive concept has been particularly shown and described with reference to embodiments thereof, it will be understood that various changes in form and details may be made therein without departing from the spirit and scope of the present invention as set forth in the following claims.

What is claimed is:

1. An electrostatic discharge (ESD) protection circuit comprising:
a first diode including an anode connected to an input/output pad and a cathode, and configured to form an ESD path of a positive charge generated in the input/output pad;
a second diode connected between the input/output pad and a second supply voltage terminal to which a ground voltage is applied, and configured to form an ESD path of a negative charge generated in the input/output pad;
a first resistor configured to limit a current flowing between the input/output pad and an input/output driver; and
a reverse blocking diode connected between the first diode and a first supply voltage terminal to which a first supply voltage greater than the ground voltage is applied,
wherein the input/output driver is connected between the first supply voltage terminal and the second supply voltage terminal.

2. The ESD protection circuit of claim 1, further comprising:
a power clamp circuit connected between the cathode of the first diode and the second supply voltage terminal.

3. The ESD protection circuit of claim 1, wherein the input/output driver comprises a pull-up driver and a pull-down driver which are connected in series to each other, and
wherein the first resistor is connected between a connection node of the input/output driver and the input/output pad, and
wherein the pull-up driver of the input/output driver and the pull-down driver of the input/output driver are connected to the connection node.

4. The ESD protection circuit of claim 1, wherein the first resistor includes one resistor or a plurality of resistors connected in parallel with each other.

5. The ESD protection circuit of claim 1, further comprising:
a second resistor connected in parallel with the reverse blocking diode.

6. The ESD protection circuit of claim 5, wherein the second resistor has a greater resistance than the first resistor.

7. The ESD protection circuit of claim 1, wherein a size of the reverse blocking diode is less than a size of each of the first diode and the second diode.

8. A semiconductor device comprising:
a plurality of input/output cells connected between a first power rail for providing a first supply voltage and a second power rail for providing a second supply voltage less than the first supply voltage; and
a power clamp cell configured to discharge static electricity generated in the plurality of input/output cells,
wherein each of the plurality of input/output cells includes:
an input/output driver connected between the first power rail and the second power rail;
a first diode connected to an input/output pad, and configured to form an electrostatic discharge (ESD) path of a positive charge generated in the input/output pad;
a second diode connected between the input/output pad and the second power rail, and configured to form an ESD path of a negative charge generated in the input/output pad; and
a first resistor configured to limit a current flowing between the input/output pad and the input/output driver, and
wherein the semiconductor device further comprises a reverse blocking diode connected between the first power rail and the first diode.

9. The semiconductor device of claim 8, wherein the reverse blocking diode is formed in the power clamp cell.

10. The semiconductor device of claim 8, wherein the reverse blocking diode is formed in a cell arranged adjacent to the power clamp cell.

11. The semiconductor device of claim 8, further comprising:
a second resistor connected in parallel with the reverse blocking diode,
wherein the second resistor is formed in the power clamp cell.

12. The semiconductor device of claim 8, further comprising:
a second resistor connected in parallel with the reverse blocking diode,
wherein the second resistor is formed in a cell arranged adjacent to the power clamp cell.

13. The semiconductor device of claim 8, wherein:
the input/output driver includes a pull-up driver and a pull-down driver which are connected in series with each other between the first power rail and the second power rail,
an area in which the pull-up driver is formed and an area in which the first diode is formed are arranged in parallel in a first horizontal direction, and
an area in which the pull-down driver and an area in which the second diode is formed are arranged in parallel in the first horizontal direction.

14. The semiconductor device of claim 13, wherein the first diode is formed by a PN junction of an N-well and a P-type region formed on the N-well, and
wherein the second diode is formed by a PN junction of a P-well and an N-type region formed on the P-well.

15. The semiconductor device of claim 13, wherein the first resistor is arranged between the area in which the pull-up driver is formed and the area in which the first diode is formed.

16. The semiconductor device of claim 8, wherein the input/output driver includes a pull-up driver and a pull-down driver which are connected in series with each other between the first power rail and the second power rail, and
wherein an area in which the pull-up driver is formed and an area in which the pull-down driver is formed are arranged in parallel in a second horizontal direction.

17. The semiconductor device of claim 16, wherein a voltage applied to a body of the pull-up driver is regulated according to a well bias control signal.

18. The semiconductor device of claim 16, wherein the pull-up driver includes a plurality of p-type transistors connected in series with each other, and
wherein the pull-down driver includes a plurality of n-type transistors connected in series with each other.

19. A semiconductor device comprising:
a first diode including an anode connected to an input/output pad and a cathode, and configured to form an electrostatic discharge (ESD) path of a positive charge generated in the input/output pad;
a second diode connected between the input/output pad and a second supply voltage terminal to which a second supply voltage is applied, and configured to form an ESD path of a negative charge generated in the input/output pad;
a bias generating circuit configured to generate a first reference voltage and a second reference voltage by distributing a voltage between the second supply voltage and a first supply voltage greater than the second supply voltage;
an input/output driver connected between a first supply voltage terminal to which the first supply voltage is applied and a second supply voltage terminal to which the second supply voltage is applied; and
a reverse blocking diode connected between the first supply voltage terminal and the first diode,
wherein the input/output driver includes:
a plurality of p-type transistors connected in series with each other between the first supply voltage terminal and the input/output pad; and
a plurality of n-type transistors connected in series between the second supply voltage terminal and the input/output pad.

20. The semiconductor device of claim 19, wherein:
a gate terminal of a first p-type transistor from among the plurality of p-type transistors and a gate terminal of a first n-type transistor from among the plurality of n-type transistors are configured to receive a driving signal,
a gate terminal of a second p-type transistor from among the plurality of p-type transistors is configured to receive the first reference voltage, and
a gate terminal of a second n-type transistor from among the plurality of n-type transistors is configured to receive the second reference voltage.
